(19) United States
(12) Patent Application Publication
(10) Pub. No.: US 2022/0383191 A1
(43) Pub. Date: Dec. 1, 2022

(54) DATA PROCESSING SYSTEM AND DATA PROCESSING METHOD

(71) Applicant: Hitachi, Ltd., Tokyo (JP)

(72) Inventors: Takahiro Naruko, Tokyo (JP); Hiroaki Akutsu, Tokyo (JP)

(73) Assignee: Hitachi, Ltd., Tokyo (JP)

(21) Appl. No.: 17/722,584

(22) Filed: Apr. 18, 2022

(30) Foreign Application Priority Data
May 28, 2021 (JP) 2021-089677

(51) Int. Cl. G06N 20/00; H03M 7/30

(52) U.S. Cl. CPC G06N 20/00; H03M 7/6064; H03M 7/70

(57) ABSTRACT

Provided is a data processing system comprising a compression/expansion unit configured by including a compressor which compresses data, and an expander which expands the data compressed by the compressor, wherein the compression/expansion unit comprises a first interface unit capable of outputting configuration information of the compressor, and a second interface unit capable of outputting the data compressed by the compressor.

### TECHNICAL FIELD

The present invention generally relates to AI (Artificial Intelligence) which processes compressed data.

### BACKGROUND ART

Known is a storage system which reduces the data volume (see PTL 1). This type of storage system generally reduces the data volume by compressing data. As one type of existing compression method, known is a method, such as the run-length method, of creating a dictionary of character strings with a high appearance frequency within predetermined block units, and replacing them with codes of a smaller size.

The lossy compression technique is known as a technology capable of reducing the data volume more than the lossless compression technique such as the run-length method (see PTL 2). For example, the storage system described in PTL 2 is a storage system which compresses and stores data based on a compression technique using a neural network. Data is compressed by modeling the regularity of data with a neural network.

Known is a technology of analyzing with AI, at a high speed, data compressed with a compression technique using a neural network (see NPTL 1). For example, the technology described in NPTL 1 is a technology of speeding up the expansion processing of compressed data by altering the AI so that the data that was compressed (compressed data) can be directly input. The type of AI disclosed in NPTL 1 is hereinafter referred to as “high-speed expansion AI”.

### CITATION LIST

### Patent Literature

[PTL 1] Japanese Unexamined Patent Application Publication No. 2007-199891
[PTL 2] Japanese Unexamined Patent Application Publication No. 2019-095913

### Non-Patent Literature

[NPTL 1] Robert Torfason, Fabian Mentzer, Eirikur Agustsson, Michael Tschannen, Radu Timofte, Luc Van Gool, “Towards Image Understanding from Deep Compression without Decoding”, 2018.

### SUMMARY OF THE INVENTION

### Problems to be Solved by the Invention

From the perspective of reducing the accumulation cost of data, lossy compression having a high compression ratio is demanded for the accumulation of large-scale data generated by IoT (Internet-of-Things) devices. Moreover, the high-speed analysis of large-scale data with AI is also being demanded. In order to balance the foregoing requirements, considered may be a system which analyzes, at a high speed, the data subject to lossy compression and accumulated by the storage system described in PTL 2 based on high-speed expansion AI.

For the design and learning of high-speed expansion AI, configuration Information of the compressor (for example, size of tensor of compressed data, range of values, compressor body and the like) for generating compressed data to become the input is required. This is because the structure of high-speed expansion AI needs to be designed so that the size of tensor and range of values received as inputs by the high-speed expansion AI coincide with the size and range of values of the compressed data.

Moreover, in order to generate the learning data of high-speed expansion AI, a compressor body is required. For example, in the learning of AI that performs image classification, generally speaking, a pair of the image data and the label data representing the class is the learning data. Meanwhile, in the learning of high-speed expansion AI, a pair of the compressed data and the label data is required as the learning data. Thus, a compressor body for generating the compressed data corresponding to the image data for learning is required.

Moreover, when analyzing data with high-speed expansion AI, compressed data, and not expanded data, is required.

Nevertheless, since the storage system described in PTL 2 internally performs the compression processing and the expansion processing transparently, it is not possible to access the compressor body or the compressor's configuration information from outside the storage system. Moreover, it is not possible to acquire the compressed data before expansion from outside the storage system. Thus, there is a problem in that this type of storage system is unable to use high-speed expansion AI, and the expansion time upon analyzing data becomes longer.

The present invention was devised in view of the foregoing points, and an object of the present invention is to propose a data processing system and a data processing method capable of providing high-speed expansion AI capable of using a compression/expansion unit which performs compression and expansion.

### Means to Solve the Problems

In order to achieve the foregoing object, the present invention provides a data processing system comprising a compression/expansion unit configured by including a compressor which compresses data, and an expander which expands the data compressed by the compressor, wherein the compression/expansion unit comprises: a first interface unit capable of outputting configuration information of the compressor; and a second interface unit capable of outputting the data compressed by the compressor.

According to the configuration described above, since the compressor's configuration information is output, for example, it is possible to generate high-speed expansion AI capable of inferring the analytical processing and the like with the data compressed by the compressor as the input, and perform inference using the generated high-speed expansion AI. Moreover, according to the configuration described above, since the data compressed by the compressor of the compression/expansion unit is input to the high-speed expansion AI without being expanded, the expansion time in the inference can be shortened.

### Advantageous Effects of the Invention

According to the present invention, it is possible to provide high-speed expansion AI capable of using a compression/expansion unit that performs compression and expansion.

### BRIEF DESCRIPTION OF DRAWINGS

FIG. 1 is a diagram explaining an overview of the data processing system according to the first embodiment.

FIG. 2 is a diagram showing an example of the data processing system according to the first embodiment.

FIG. 3 is a diagram showing an example of the configuration of the RAM according to the first embodiment.

FIG. 4 is a diagram showing an example of the configuration of the RAM according to the first embodiment.

FIG. 5 is a diagram showing an example of the configuration of the compressor configuration information table according to the first embodiment.

FIG. 6 is a diagram showing an example of the draw write processing according to the first embodiment.

FIG. 7 is a diagram showing an example of the expanded data read processing according to the first embodiment.

FIG. 8 is a diagram showing an example of the compressed data read processing according to the first embodiment.

FIG. 9 is a diagram showing an example of the compressor configuration information return processing according to the first embodiment.

FIG. 10 is a diagram showing an example of the high-speed expansion AI learning processing according to the first embodiment.

FIG. 11 is a diagram showing a generation example of the high-speed expansion AI model according to the first embodiment.

FIG. 12 is a diagram showing an example of the high-speed expansion AI analytical processing according to the first embodiment.

FIG. 13 is a diagram showing an example of the configuration of the compressor and the coder according to the first embodiment.

### DESCRIPTION OF EMBODIMENTS

### (I) First Embodiment

An embodiment of the present invention is now explained in detail. This embodiment relates to the reduction of data volume and high-speed analytical processing. Nevertheless, the present invention is not limited to the embodiments.

A data processing system of this embodiment comprises a compression/expansion unit configured by including a compressor which compresses data, and an expander which expands the data compressed by the compressor (compressed data). The compressor and the expander are, for example, neural networks. The compression/expansion unit uses a first interface to return the compressor's configuration information in response to a request from the outside. Furthermore, the data processing system comprises a library which generates a compressor model and a high-speed expansion AI model based on the acquired configuration information, and the AI learning program can design and learn high-speed expansion AI based on the library. Furthermore, the compression/expansion unit uses a second interface to return the compressed data before expansion in response to a request from the outside.

According to the configuration described above, for example, since high-speed expansion AI can be used in a system which compresses and accumulates data with a compressor using a neural network, the expansion processing at the time of analysis can be sped up in comparison to the technology described in PTL 2.

An embodiment of the present invention is now explained with reference to the appended drawings. The following descriptions and drawings are exemplifications for explaining the present invention, and certain descriptions are omitted or simplified as needed for clarifying the explanation of the present invention. The present invention can also be worked in other various modes. Unless specifically limited herein, each constituent element may be singular or plural.

Moreover, expressions such as “first”, “second”, “third” and the like in the present specification and the drawings are affixed for identifying the constituent elements, and are not necessarily limited to quantity or order. Moreover, the numbers used for identifying the constituent elements are used for each context, and a number used in one context may not necessarily refer to the same configuration in another context. Moreover, a constituent element identified with a certain number is not precluded from concurrently serving the function of a constituent element identified with another number.

(1-1) Overview

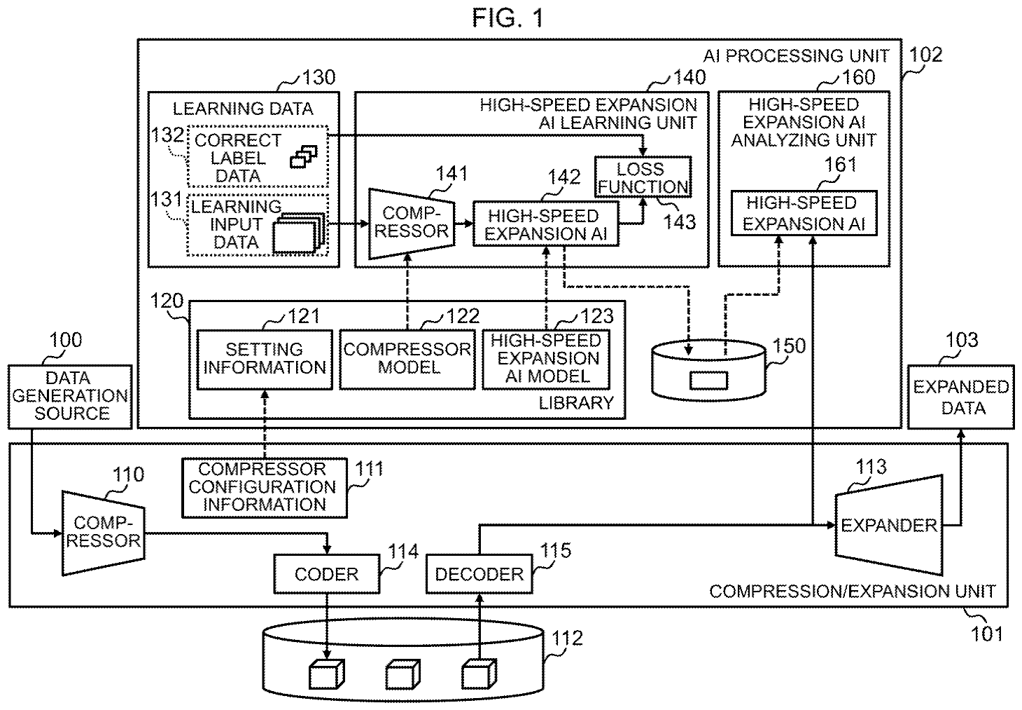

An overview of the first embodiment is now explained with reference to FIG. 1.

The data processing system of this embodiment is configured by including a data generation source 100, a compression/expansion unit 101, an AI processing unit 102, and a storage 112.

The data generation source 100 is a subject which generates the data to be accumulated and analyzed. The data generation source 100 is, for example, an image sensor which generates image data. The data generation source 100 and the data generated by the data generation source 100 are not limited to the above, and, for example, the data generation source 100 may also be a monitoring camera that generates video data, a vibration sensor that generates one-dimensional data, or software that generates log data. Moreover, there may be a plurality of data generation sources 100.

The compression/expansion unit 101 is a module that is in charge of the compression of data and the expansion of data. The compression/expansion unit 101 comprises a compressor 110, an expander 113, a coder 114, a decoder 115 and the like. The compressor 110 and the expander 113 are, for example, neural networks, and configured by using an encoder part and a decoder part of an auto encoder.

The compression/expansion unit 101 converts data into compressed data with the compressor 110 in response to a write request of data from the data generation source 100, thereafter converts the data into a bit sequence with the coder 114, and stores the bit sequence in the storage 112.

In response to a read request of the data that was expanded (expanded data 103), the compression/expansion unit 101 reads the bit sequence of the target data from the storage 112, converts the data into compressed data with the decoder 115, additionally performs expansion processing to the compressed data with the expander 113, and returns the data that was expanded (expanded data 103) to the request source.

Meanwhile, for example, when there is a request for reading the compressed data for performing analysis with the high-speed expansion AI 161, the compression/expansion unit 101 reads the bit sequence of the target data from the storage 112, and thereafter returns the compressed data that was converted (decoded) by the decoder 115 to the request source. In the foregoing case, since the expansion processing with the expander 113 is omitted, the expansion processing at the time of analysis is sped up in comparison to the case of responding to a read request of the expanded data.

Moreover, the compression/expansion unit 101 is managing configuration information related to the compressor 110 (compressor configuration information 111), and, when the compressor configuration information 111 is requested, the compression/expansion unit 101 returns the compressor configuration information 111 to the request source.

The AI processing unit 102 is a module that performs the learning of the high-speed expansion AI 142, and the analysis based on the high-speed expansion AI 161, which is the AI that learned the high-speed expansion AI 142. The AI processing unit 102 comprises a library 120, a high-speed expansion AI learning unit 140, a high-speed expansion AI analyzing unit 160 and the like.

The library 120 is a library that provides a model of the compressor 141 (compressor model 122) and a model of the high-speed expansion AI 142 (high-speed expansion AI model 123) required for the learning of the high-speed expansion AI 142.

The high-speed expansion AI learning unit 140 is a program that performs the learning of the high-speed expansion AI 142. The high-speed expansion AI learning unit 140 inquires the compressor configuration information 111 to the compression/expansion unit 101, and sets the compressor configuration information 111 as the setting information 121 in the library 120. The library 120 generates the learned compressor model 122 and the unlearned high-speed expansion AI model 123 based on the setting information 121. The high-speed expansion AI learning unit 140 uses the loss function 143 and learns the high-speed expansion AI 142, in which the high-speed expansion AI model 123 has been operably read therein, so as to output the correct label data 132 with the compressed data obtained by compressing the data (learning input data 131) to become the input of the high-speed expansion AI 142, among the learning data 130, with the compressor 141 in which the compressor model 122 has been operably read therein. After completing the learning, the high-speed expansion AI learning unit 140 stores the model of the learned high-speed expansion AI 142 in the storage 150.

The high-speed expansion AI analyzing unit 160 is a program which acquires the model of the learned high-speed expansion AI 142 from the storage 150, and analyzes the data accumulated in the storage 112 by using the high-speed expansion AI 161 in which the model of the high-speed expansion AI 142 has been operably read therein.

The high-speed expansion AI analyzing unit 160 requests the compression/expansion unit 101 to read the compressed data, executes the high-speed expansion AI 161 with the acquired compressed data as the input, and obtains the analytical finding.

(1-2) Configuration of Data Processing System

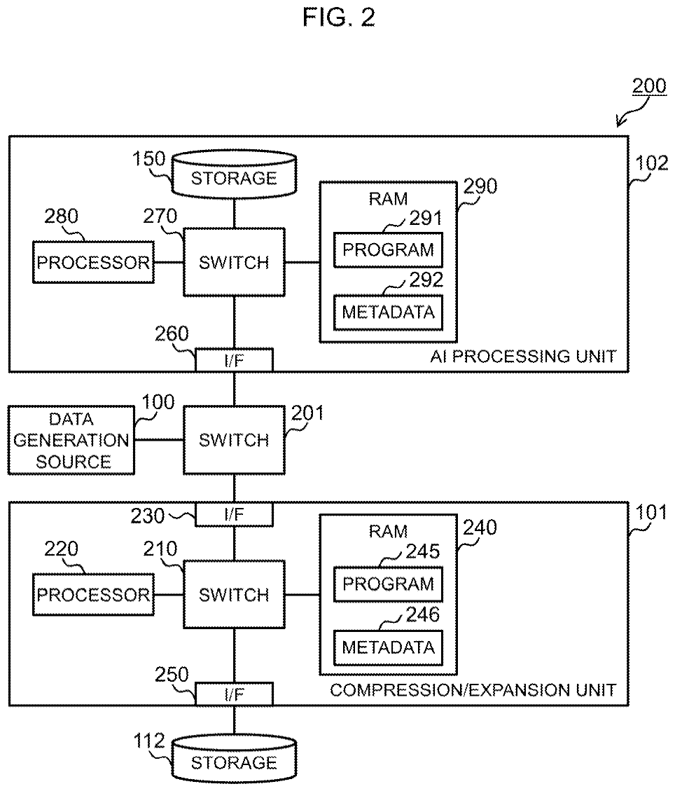

An example of the data processing system (data processing system 200) of this embodiment is now explained with reference to FIG. 2.

The compression/expansion unit 101 and the AI processing unit 102 are each a computer comprising hardware resources such as a processor, a memory, and a network interface, and software resources such as a compressor, and an expander. The switch 201 mutually connects the data generation source 100, the compression/expansion unit 101, and the AI processing unit 102.

The compression/expansion unit 101 is configured by including a switch 210, a processor 220, an I/F 230 (Front-end Interface), a RAM 240, and an I/F 250 (Back-end Interface). The I/F 230 is an interface for connecting the compression/expansion unit 101, the data generation source 100 and the AI processing unit 102. The processor 220 controls the overall compression/expansion unit 101 via the switch 210 based on the program 245 and the management information 246 (Metadata) recorded in the RAM 240. The I/F 250 connects the compression/expansion unit 101 and the storage 112.

The AI processing unit 102 is configured by including a storage 150, an I/F 260 (Front-end Interface), a switch 270, a processor 280, and a RAM 290. The I/F 260 is an interface for connecting the AI processing unit 102, the compression/expansion unit 101 and the like. The processor 280 controls the overall AI processing unit 102 via the switch 270 based on the program 291 and the management information 292 (Metadata) recorded in the RAM 290.

The processor 220 and the processor 280 may be a general-purpose arithmetic processor such as a CPU (Central Processing Unit), an accelerator such as a GPU (Graphical Processing Unit) or an FPGA (Field Programmable Gate Array), or a combination of the above.

The storage 112 and the storage 150 may be a block device configured from an HDD (Hard Disk Drive) or an SSD (Solid State Drive), a file storage, a contents storage, a volume built in the storage system, or realized with an arbitrary method which accumulates data.

The compression/expansion unit 101 and the AI processing unit 102 may have a configuration in which hardware such as an IC (Integrated Circuit) and the like are mutually connected and equipped with the constituent elements explained above, and several of such constituent elements may have a configuration of being mounted on one semiconductor device as an ASIC (Application Specific Integrated Circuit), an FPGA or the like. Moreover, the compression/expansion unit 101 and the AI processing unit 102 may be different hardware devices, different VMs (Virtual Machines) that run on the same computer, different containers that run on the same OS (Operating System), or different applications that run on the same OS. For example, the compression/expansion unit 101, the AI processing unit 102, and the storage 112 may also be individual software that runs on an HCI (Hyper Converged Infrastructure). Moreover, the compression/expansion unit 101 and the AI processing unit 102 may also be realized with a cluster configured from a plurality of computers.

(1-3) RAM Configuration

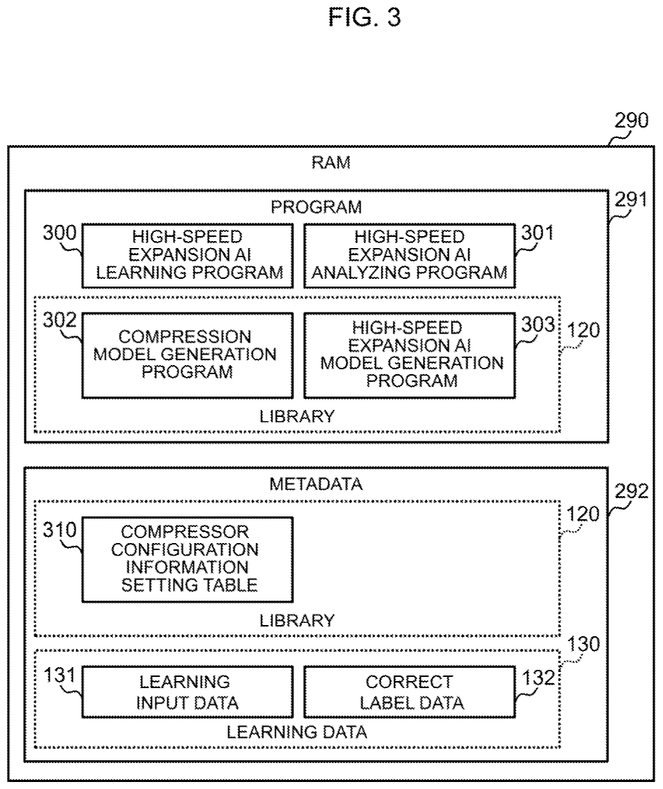

FIG. 3 shows an example of the configuration of the RAM 290 of the AI processing unit 102. The RAM 290 includes a program 291 to be executed by the processor 280 of the AI processing unit 102, and management information 292 to be used by the program 291.

The program 291 is configured by including a high-speed expansion AI learning program 300, a high-speed expansion AI analyzing program 301, a compressor model generation program 302, and a high-speed expansion AI model generation program 303. The management information 292 is configured by including a compressor configuration information setting table 310, learning input data 131, and correct label data 132. Among the above, the compressor model generation program 302, the high-speed expansion AI model generation program 303, and the compressor configuration information setting table 310 are the programs and management information included in the library 120. Moreover, the learning data 130 may also be stored in the storage 150 instead of being stored in the RAM 290.

The high-speed expansion AI learning program 300 is a program that performs the learning of the high-speed expansion AI 142 by using the learning data 130 configured from the learning input data 131 and the correct label data 132.

The high-speed expansion AI analyzing program 301 is a program that performs the analysis of the data accumulated in the storage 112 by using the high-speed expansion AI 142 that completed the learning with the high-speed expansion AI learning program 300; that is, by using the high-speed expansion AI 161.

The compressor model generation program 302 is a program that generates the compressor model 122, which is a model of the learned compressor 141 required for the learning of the high-speed expansion AI 142, based on the configuration information of the compressor 110 set in the compressor configuration information setting table 310.

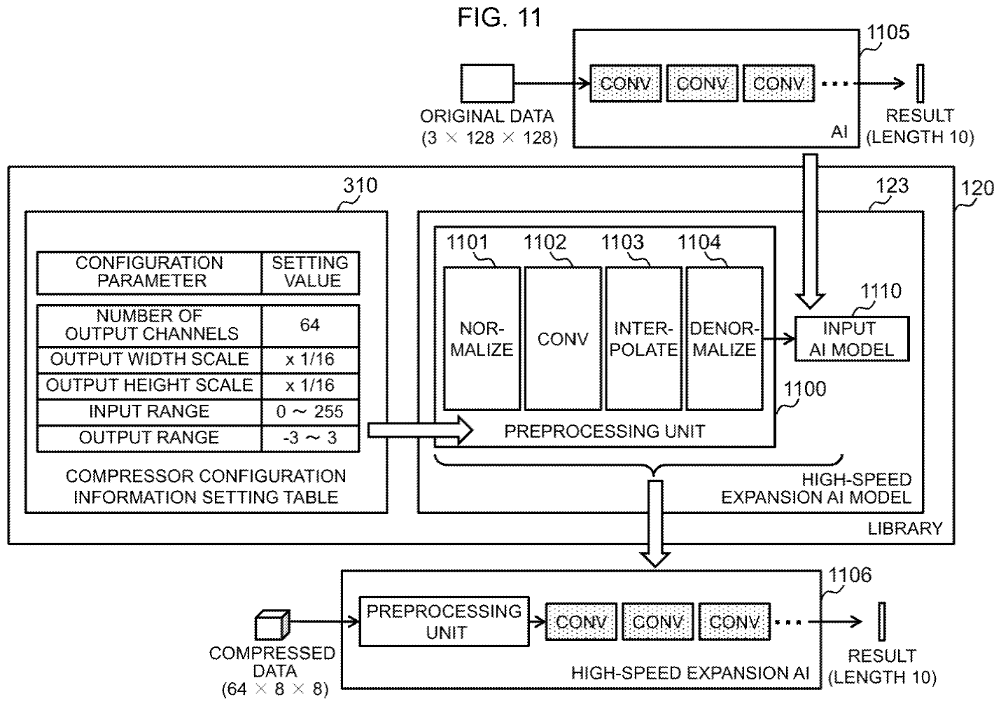

The high-speed expansion AI model generation program 303 is a program that converts a model of prescribed AI given as an input (input AI model) into the high-speed expansion AI model 123 based on the configuration information of the compressor 110 set in the compressor configuration information setting table 310. Nevertheless, the high-speed expansion AI model 123 is generated in an unlearned state. For example, the high-speed expansion AI model generation program 303 generates a model of a neural network of the high-speed expansion AI capable of identifying numbers, with the compressed data of an image as the input, when a model of a neural network that identifies numbers appearing in the image is given with the image as the input. Details will be described later with reference to FIG. 11.

The compressor configuration information setting table 310 is a table that manages the compressor configuration information 111 (configuration information of the compressor 110) acquired from the compression/expansion unit 101.

The learning input data 131 and the correct label data 132 are the learning data to be used in the learning of the high-speed expansion AI 142. For example, when the high-speed expansion AI 142 is AI that identifies the numbers appearing in an image with the compressed data of the image as the input, the learning input data 131 is the image group in which the numbers appear, and the correct label data 132 is the label group expressing the numbers appearing in each image. Note that the configuration of the learning data 130 is not limited to a pair of the learning input data 131 and the correct label data 132. For example, when learning AI that performs unsupervised learning, the correct label data 132 is not required. Moreover, when learning the high-speed expansion AI 142 that simultaneously executes a plurality of tasks to the input, the learning data 130 may include a plurality of types of correct label data 132. Moreover, when using the data accumulated in the storage 112 in learning, the learning data 130 does not need to include the learning input data 131.

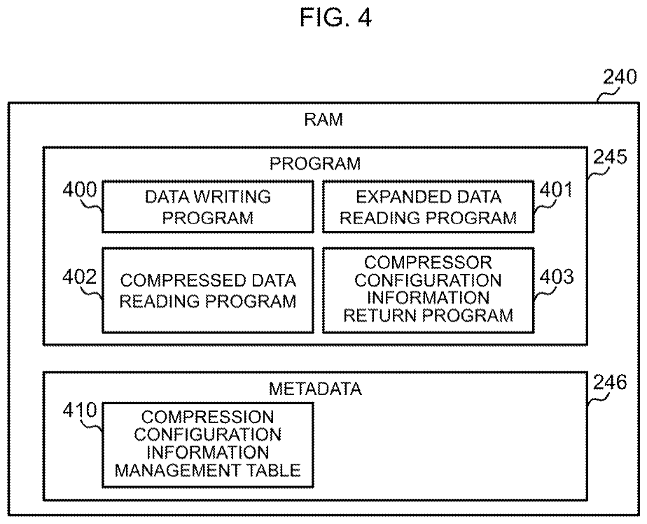

FIG. 4 shows an example of the configuration of the RAM 240 of the compression/expansion unit 101. The RAM 240 includes a program 245 to be executed by the processor 220 of the compression/expansion unit 101, and management information 246 to be used by the program 245.

The program 245 is configured by including a data writing program 400, an expanded data reading program 401, a compressed data reading program 402, and a compressor configuration information return program 403. The management information 246 is configured by including a compressor configuration information management table 410.

The data writing program 400 is a program that compresses the data received from the data generation source 100 with the compressor 110, converts the data into a bit sequence with the coder 114, and stores the bit sequence in the storage 112.

The expanded data reading program 401 is a program that reads the bit sequence of the corresponding data from the storage 112 in response to a read request of the expanded data from the outside, decodes the compressed data with the decoder 115, and thereafter returns, to the request source, the expanded data that underwent the expansion processing of the expander 113.

The compressed data reading program 402 is a program that reads the bit sequence of the corresponding data from the storage 112 in response to a read request of the compressed data from the outside, and returns, to the request source, the compressed data decoded by the decoder 115.

The compressor configuration information return program 403 is a program that reads the compressor configuration information 111 from the compressor configuration information management table 410 in response to an acquisition request of the compressor configuration information 111 from the outside, and returns the compressor configuration information 111 to the request source.

The compressor configuration information management table 410 is a table for managing the compressor configuration information 111.

(1-4) Table Configuration

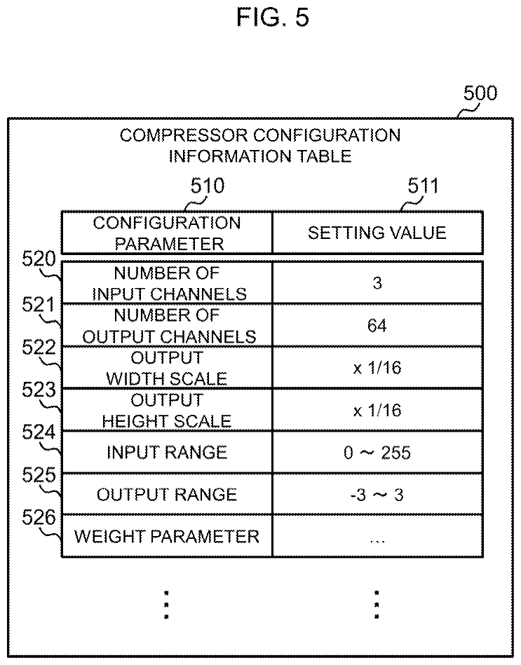

FIG. 5 shows an example of the configuration of the compressor configuration information table 500. The compressor configuration information setting table 310 and the compressor configuration information management table 410 retain the compressor configuration information 111 based on the format of the compressor configuration information table 500. Note that the mode of expression of the compressor configuration information 111 is not limited to the format of the compressor configuration information table 500, and may also be expressed with a data structure other than a table such as in the form of XML (Extensible Markup Language), YAML (YAML Ain't a Markup Language), a hash table, or a tree structure.

The compressor configuration information table 500 is a table that manages the setting values included in the setting value column 511 regarding the parameters of the compressor 110 indicated in the configuration parameter column 510. FIG. 5 shows an example of the parameters being managed in the compressor configuration information table 500. Note that the parameters being managed in the compressor configuration information table 500 may exist other than the parameters shown in FIG. 5, or the parameters shown in FIG. 5 may be excluded.

The number of input channels 520 represents the number of channels of the tensor input by the compressor 110. The number of output channels 521 represents the number of channels of the tensor output by the compressor 110. The output width scale 522 represents how many times the width of the output tensor of the compressor 110 is greater relative to the width of the input tensor of the compressor 110. The output height scale 523 represents how many times the height of the output tensor of the compressor 110 is greater relative to the height of the input tensor of the compressor 110. The input range 524 represents the range of values that may be taken by each element of the tensor input by the compressor 110. The output range 525 represents the range of values that may be taken by each element of the tensor output by the compressor 110.

For example, the configuration shown in FIG. 5 represents that the compressor 110 receives, as the input, three-channel three-dimensional data in which the value of each element that takes on a value of 0 or more and 255 or less of an RGB image or the like, and outputs a tensor in which the value of each element is −3 or more and 3 or less, number of channels is 64, and height and width are respectively 1/16 the size of the input.

The weight parameter 526 expresses the learned parameters such as the weight and bias of the neural network configuring the compressor 110. The parameters may be expressed with an arbitrary data structure such as a Dictionary, ONNX (Open Neural Network eXchange) format or the like.

(1-5) Data Write Processing

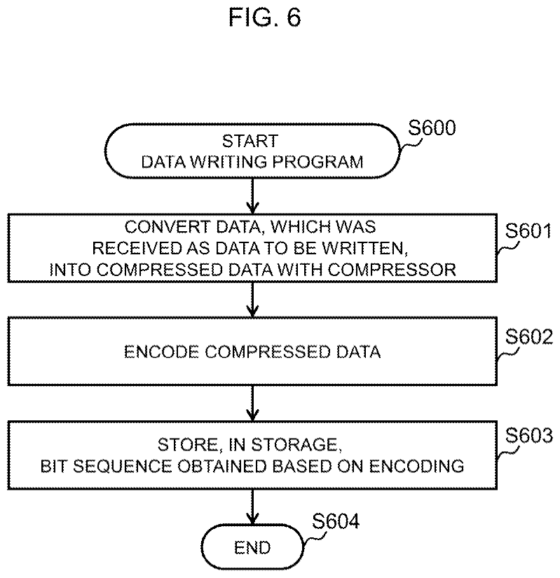

FIG. 6 is a flowchart of the data writing program 400. The processor 220 of the compression/expansion unit 101 starts the data writing program 400 when the I/F 230 receives a data write request from the data generation source 100 (S600).

In S601, the processor 220 acquires the data to be written that was received by the I/F 230, and converts the data into compressed data with the compressor 110.

In S602, the processor 220 converts the compressed data that was converted (generated) in S601 into a bit sequence with the coder 114. For example, simply put, the compressed data is encoded by binarizing the 32-bit floats of each element of the tensor based on the Raster-scan Order. Moreover, in order to improve the compression ratio, it is also possible to cause the compressed data to undergo entropy encoding based on an arithmetic code or the like. Nevertheless, the encoding method is not limited to the methods described above.

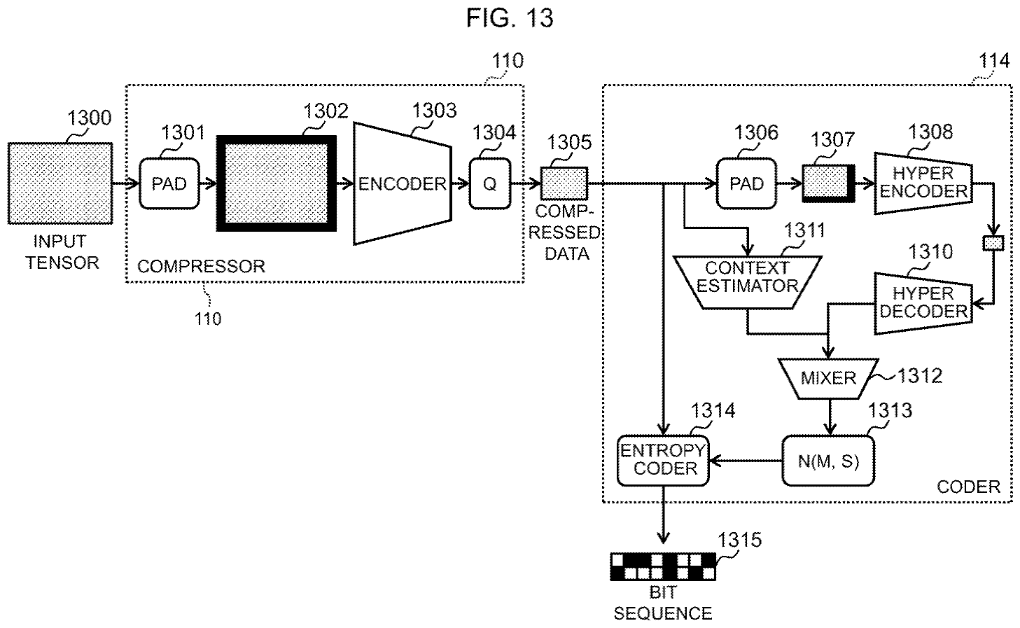

An example of the configuration of the compressor 110 and the coder 114 in the case of performing entropy encoding is shown in FIG. 13. Nevertheless, the configuration of the compressor 110 and the coder 114 is not limited to the foregoing configuration.

The compressor 110 is configured from a padder 1301, an encoder 1303, and a quantizer 1304. The encoder 1303 is, for example, an encoder part of an auto encoder configured from a convolution neural network. A convolution neural network is configured from a convolution layer, a batch normalization layer, an activating function and the like, and generally outputs a tensor configured from a real number. The quantizer 1304 performs processing for rounding the value of each element of the tensor output by the encoder 1303 to a discrete value. For example, the quantizer 1304 a quantizer which rounds the value of each element to the nearest integer value, or a quantizer which substitutes the value of each element with the nearest value among a finite number of values defined in advance. Moreover, the quantizer 1304 may also be another arbitrary quantizer.

The encoder 1303 generally outputs a tensor having a size in the spatial direction that is smaller than the input tensor 1300 based on the Pooling layer or the convolution layer with a Stride. For example, in the case of a convolution neural network including 4 stages of convolution layers in which the Stride is “2”, a tensor in which the size of each axis of the input tensor 1300 in the spatial direction is reduced to 1/16 is output. When the input tensor 1300 includes an axis in the spatial direction in which the size is not a multiple of 16, the padder 1301 adds (pads) elements to the input tensor 1300 so that the size of that axis becomes a minimum multiple of 16 which is larger than the original size.

The padder 1301 may be, for example, zero-padding of adding “0”, or any other arbitrary value may be added. For example, when the size of the input tensor 1300 in the spatial direction is a width of 126 pixels and a height of 129 pixels, the padder 1301 generates the tensor 1302 having a width of 128 pixels and a height of 144 pixels by inserting “0” for 1 pixel each on the left and right, and for 8 pixels at the top and for 7 pixels at the bottom, and the encoder 1303 and the quantizer 1304 generate the compressed data 1305 having a width of 8 pixels and a height of 9 pixels.

The coder 114 is configured from a padder 1306, a hyper encoder 1308, a hyper decoder 1310, a context estimator 1311, a mixer 1312, a probability generator 1313, and an entropy coder 1314. The hyper encoder 1308, the hyper decoder 1310, the context estimator 1311, and the mixer 1312 are respectively configured from a neural network, and calculate the parameters for predicting the appearance probability of the value of each element of the compressed data 1305. The hyper encoder 1308 and the hyper decoder 1310 are mounted so that the size of the input tensor of the hyper encoder 1308 and the size of the output tensor of the hyper decoder 1310 become equal.

The context estimator 1311 is configured, for example, from a Masked Convolution layer. The mixer 1312 outputs the parameters required for probability prediction with the output of the hyper decoder 1310 and the output of the context estimator 1311 as the inputs. The probability generator 1313 calculates the appearance probability of the value of each element of the compressed data 1305 based on the output of the mixer 1312. For example, the output of the mixer 1312 represents the average value of each element of the compressed data 1305 and the standard deviation, and the probability generator 1313 calculates the probability of the value of each element based on Gaussian distribution expressed with these parameters. The entropy coder 1314 is, for example, an arithmetic coder, and converts the compressed data 1305 into the bit sequence 1315 by using the probability generated by the probability generator 1313.

Since the hyper encoder 1308 and the hyper decoder 1310 are configured, for example, from a convolution neural network with a Stride, similar to the encoder 1303, with the tensor 1307 to be input to the hyper encoder 1308, the size of the axis in the spatial direction needs to be a multiple of a specific integer. The padder 1306 converts the size of the compressed data 1305 and outputs the tensor 1307 so as to satisfy this condition. Similar to the padder 1301, the padder 1306 may be added with elements in which the value is “O” equally at the left, right, top and bottom, but the elements may also be added toward the bottom and right so that the coordinates of the output tensor of the context estimator 1311 and the output tensor of the hyper decoder 1310 coincide.

Moreover, elements in an amount required by the padder 1306 may also be collectively added to the padder 1301. For example, when the encoder 1303 is configured from 4 stages of Stride “2” convolution layers and the hyper encoder 1308 is configured from 2 stages of Stride “2” convolution layers, the padder 1306 may be omitted by adding elements to the padder 1301 so that the size of the spatial axis becomes a multiple of 64. Nevertheless, by adopting the configuration shown in FIG. 13 which respectively adds elements so that it becomes a multiple of 16 in the padder 1301 and becomes a multiple of 4 in the padder 1306, since the number of elements of the compressed data 1305 becomes smaller, a better compression ratio can be expected.

In S603, the processor 220 stores the bit sequence generated in S602 in the storage 112, and thereafter ends the data writing program 400 (S604).

(1-6) Expanded Data Read Processing

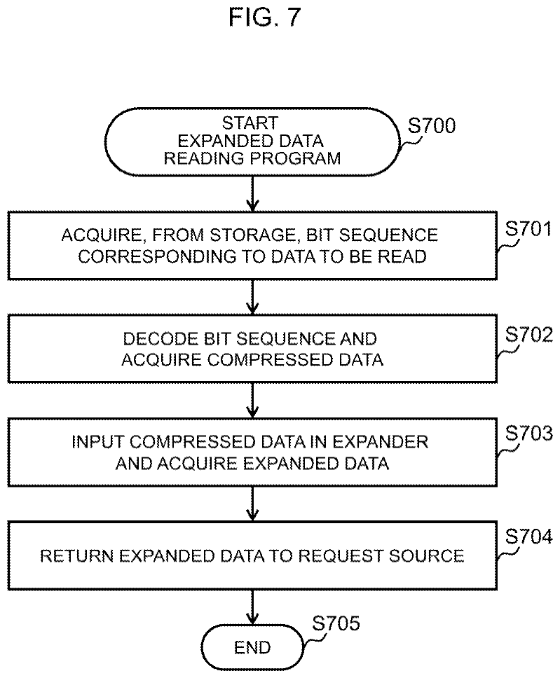

FIG. 7 is a flowchart of the expanded data reading program 401. The processor 220 of the compression/expansion unit 101 starts the expanded data reading program 401 when the I/F 230 receives a read request of expanded data (S700). Note that, while the issuer of the request is, for example, the AI processing unit 102, the issuer may otherwise be arbitrary hardware connected to the switch 201, virtualized hardware or the like.

In S701, the processor 220 acquires, from the storage 112, the bit sequence corresponding to the data to be read.

In S702, the processor 220 uses the decoder 115 and decodes the bit sequence into compressed data.

In S703, the processor 220 uses the expander 113 and expands the compressed data into data of the same format as before compression.

In S704, the processor 220 returns the expanded data acquired in S703 to the request source via the I/F 230, and thereafter ends the expanded data reading program 401 (S705).

(1-7) Compressed Data Read Processing

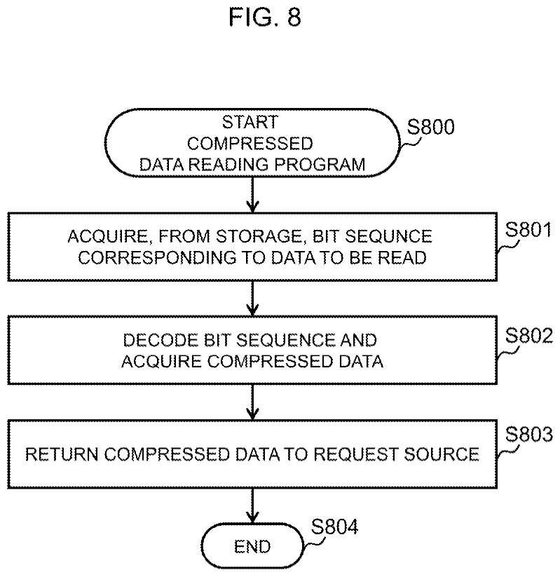

FIG. 8 is a flowchart of the compressed data reading program 402. The processor 220 of the compression/expansion unit 101 starts the compressed data reading program 402 when the I/F 230 receives a read request of compressed data (S800). Note that, while the issuer of the request is, for example, the AI processing unit 102, the issuer may otherwise be arbitrary hardware connected to the switch 201, virtualized hardware or the like.

In S801, the processor 220 acquires, from the storage 112, the bit sequence corresponding to the data to be read.

In S802, the processor 220 uses the decoder 115 and decodes the bit sequence into compressed data.

In S803, the processor 220 returns the compressed data acquired in S802 to the request source via the I/F 230, and thereafter ends the compressed data reading program 402 (S804).

With the compressed data reading program 402, since S703 that expands the compressed data with the expander 113, which was required in the expanded data reading program 401, is no longer required, the expansion processing at the time of analysis is sped up.

(1-8) Compressor Configuration Information Return Processing

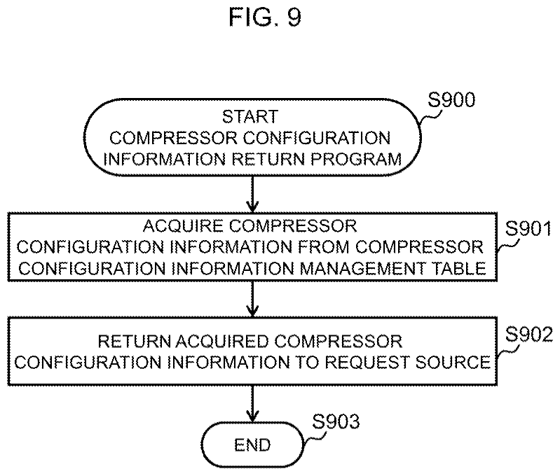

FIG. 9 is a flowchart of the compressor configuration information return program 403. The processor 220 of the compression/expansion unit 101 starts the compressor configuration information return program 403 when the I/F 230 receives an acquisition request of the compressor configuration information 111 (S900). Note that, while the issuer of the request is, for example, the AI processing unit 102, the issuer may otherwise be arbitrary hardware connected to the switch 201, virtualized hardware or the like.

In S901, the processor 220 acquires the compressor configuration information 111 from the compressor configuration information management table 410.

In S902, the processor 220 returns the compressor configuration information 111 acquired in S901 to the request source, and thereafter ends the compressor configuration information return program 403 (S903).

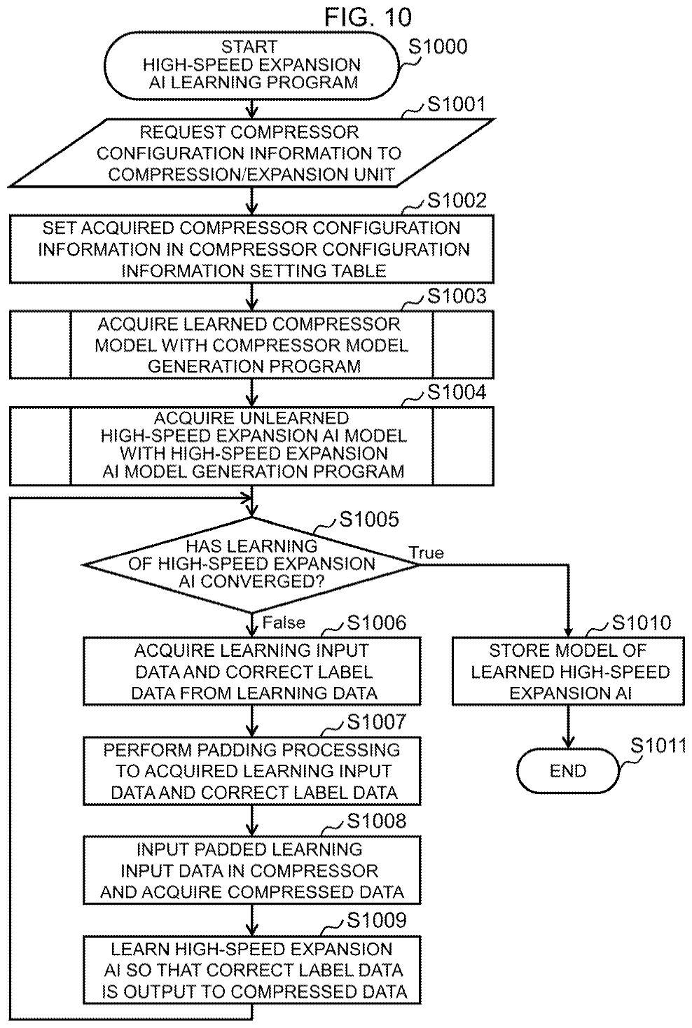

(1-9) High-Speed Expansion AI Learning Processing FIG. 10 is a flowchart of the high-speed expansion AI learning program 300. The processor 280 of the AI processing unit 102 starts the execution of the high-speed expansion AI learning program 300, for example, at the timing instructed to the AI processing unit 102 by the user with an external input device such as a keyboard, but any other arbitrary event may also be used as the trigger. Note that the high-speed expansion AI learning program 300 is described by the designer of the AI, and the flow shown in FIG. 10 is merely an example, and other processing may be described so as long as it is a program which learns the high-speed expansion AI 142 by using the library 120.

In S1001, the processor 280 requests the compressor configuration information 111 to the compression/expansion unit 101 via the I/F 250. Based on this request, the compressor configuration information return program 403 is executed in the compression/expansion unit 101, and the returned compressor configuration information 111 is received by the I/F 250.

In S1002, the processor 280 sets the compressor configuration information 111 received by the VF 250 in the compressor configuration information setting table 310. The processor 280 may write information in the compressor configuration information setting table 310 included in the library 120 according to the steps described in the high-speed expansion AI learning program 300, or by using the API (Application Programming Interface) provided by the library 120.

In S1003, the processor 280 calls the subroutine of the compressor model generation program 302 and acquires the learned compressor model 122. The compressor model generation program 302 generates the compressor model 122 based on the neural network structure of the compressor 110 and the information of the weight parameter 526 stored in the compressor configuration information setting table 310.

In S1004, the processor 280 calls the subroutine of the high-speed expansion AI model generation program 303, and acquires the unlearned high-speed expansion AI model 123. The high-speed expansion AI model generation program 303 generates the high-speed expansion AI model 123 based on the configuration information of the compressor 110 stored in the compressor configuration information setting table 310, and the input AI model given as an argument of the high-speed expansion AI model generation program 303.

A generation example of the high-speed expansion AI model 123 is shown in FIG. 11. As the neural network of the input AI model 1110, anticipated is the AI 1105 which identifies the numbers appearing in the RGB image and outputs a one-hot vector having a length of 10 with an RGB image of 128×128 as the input. Moreover, as the compressor 110, anticipated is a type which outputs a 64-channel tensor in which the width and height are respectively 1/16 (range of values of each element is −3 or more and 3 or less) with the RGB image (range of values of each element is 0 or more and 255 or less) as the input.

In the foregoing case, the high-speed expansion AI model generation program 303 builds the preprocessing unit 1100 of converting compressed data in which the range of values is −3 to 3 and the size is 64×8×8 into a tensor in which the range of values is 0 to 255 and the size is 3×128×128 based on the configuration information of the compressor 110 stored in the compressor configuration information setting table 310.

The preprocessing unit 1100 can be configured, for example, from a normalization layer 1101 which converts the range of values from −3 to 3 to −1 to 1, a convolution layer 1102 which converts a 64-channel tensor into a 3-channel tensor, and an interpolation layer 1103 which expands the width and height of the tensor 16-fold, respectively, based on linear interpolation by dividing the value of each element by “3”, and a denormalization layer 1104 which converts the range to 0 to 255 by increasing the value of each element 255-fold. As described above, the high-speed expansion AI model generation program 303 can generate the high-speed expansion AI model 123 of the high-speed expansion AI 1106 which outputs a vector having a length of 10, with the compressed data as the input, by connecting the generated preprocessing unit 1100 and the given input AI model 1110.

Nevertheless, the preprocessing unit 1100 may also be generated according to a method other than the method described above. Moreover, as with the compressor 110, when the AI 1105 is configured from a convolution neural network or the like, the high-speed expansion AI model generation program 303 may generate the high-speed expansion AI model 123, in substitute for generating the preprocessing unit 1100, by removing the convolution layer of the preliminary stage of the input AI model 1110 so that a tensor of a size of the compressed data can be input, or generate the high-speed expansion AI model 123 by changing the Stride of the convolution layer of the preliminary stage of the input AI model 1110 to “1” or removing the Pooling layer.

In S1006, the processor 280 samples and acquires the learning input data 131 and the correct label data 132 from the learning data 130.

In S1007, the processor 280 performs padding processing to the learning input data 131 and the correct label data 132 acquired in S1006. Padding processing includes, for example, processing of randomly rotating, inverting and resizing, and processing of cutting the data into patches of the same size. If padding processing is not required, then this step may be omitted.

In S1008, the processor 280 inputs the learning input data 131 generated in S1007 to the compressor 141 in which the compressor model 122 acquired in S1003 has been executably loaded in the RAM 290, and acquires compressed data.

In S1009, the processor 280 updates the parameters of the high-speed expansion AI 142 in which the high-speed expansion AI model 123 acquired in S1004 has been executably loaded in the RAM 290 so as to output the correct label data 132 generated in 1007 with the compressed data generated in S1008 as the input. For example, the processor 280 inputs the compressed data to the high-speed expansion AI 142 configured from a neural network, evaluates the difference between the output value and the correct label data 132 based on the loss function 143, calculates a derivative value in each parameter based on back propagation or the like, and updates the respective parameters based on an optimization algorithm such as Adam. Nevertheless, the learning algorithm of the high-speed expansion AI 142 is not limited to the above.

S1006 to S1009 are repeatedly executed until a prescribed condition, such as the convergence of learning of the high-speed expansion AI 142, is satisfied (S1005).

Once the learning is complete, the processor 280 stores the model of the learned high-speed expansion AI 142 in the storage 150, and thereby ends the high-speed expansion AI learning program 300 (S1011).

(1-10) High-Speed Expansion AI Analytical Processing

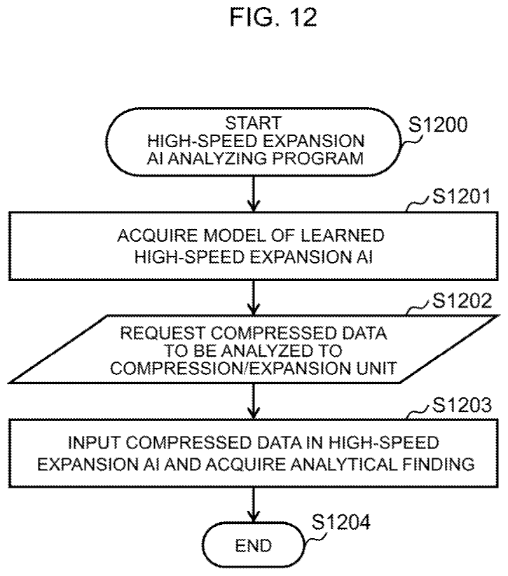

FIG. 12 is a flowchart of the high-speed expansion AI analyzing program 301. The processor 280 of the AI processing unit 102 starts the execution of the high-speed expansion AI analyzing program 301, for example, at the timing instructed to the AI processing unit 102 by the user with an external input device such as a keyboard, but any other arbitrary event may also be used as the trigger. Note that the high-speed expansion AI analyzing program 301 is described by the designer of the AI, and the flow shown in FIG. 12 is merely an example, and other processing may be described so as long as it includes the step of executing the high-speed expansion AI 161.

In S1201, the processor 280 acquires the model of the learned high-speed expansion AI 142 from the storage 150.

In S1202, the processor 280 requests the compressed data to be analyzed to the compression/expansion unit 101 via the I/F 250. The compressed data reading program 402 is executed by the compression/expansion unit 101 based on the request, and the returned compressed data is received by the I/F 250.

In S1203, the processor 280 inputs the compressed data received by the I/F 250 to the high-speed expansion AI 161 in which the model of the high-speed expansion AI 142 acquired in S1201 has been executably loaded in the RAM 290, and acquires the analytical finding. The processor 280 thereby ends the high-speed expansion AI analyzing program 301 (S1204).

Note that the processor 280 may analyze a plurality of data based on the high-speed expansion AI 161 by repeating S1202 to S1203, or processing for additionally processing the analytical finding obtained in S1203 may be performed subsequent to S1203.

An example of a system to which the present invention has been applied was explained above.

(11) Supplementary Notes

The embodiments described above include, for example, the following subject matter.

While the foregoing embodiments explained a case of applying the present invention to a data processing system, the present invention is not limited thereto, and may also be broadly applied to various other types of systems, devices, methods, and programs.

Moreover, a part or all of the programs in the foregoing embodiment may be installed from a program source to a device such as a computer which realizes the compression/expansion unit 101, the AI processing unit 102 and the like. The program source may also be, for example, a program distribution server connected to a network or a computer-readable storage medium (for example, non-temporary storage medium). Moreover, in the foregoing explanation, two or more programs may be realized as one program, and one program may be realized as two or more programs.

The embodiments described above include, for example, the following characteristic configurations.

(1)

A data processing system (for example, data processing system 200) comprising a compression/expansion unit (for example, compression/expansion unit 101) configured by including a compressor (for example, compressor 110) which compresses data, and an expander (for example, expander 113) which expands the data compressed by the compressor, wherein the compression/expansion unit comprises: a first interface unit (for example, compressor configuration information return program 403, processor 220, circuit) capable of outputting configuration information of the compressor; and a second interface unit (for example, compressed data reading program 402, processor 220, circuit) capable of outputting the data compressed by the compressor.

The compression/expansion unit may be provided in a storage, or may be a CVM, a container, an application or the like.

According to the configuration described above, since the compressor's configuration information is output, for example, it is possible to generate high-speed expansion AI capable of inferring the analytical processing and the like with the data compressed by the compressor as the input, and perform inference using the generated high-speed expansion AI. Moreover, according to the configuration described above, since the data compressed by the compressor of the compression/expansion unit is input to the high-speed expansion AI without being expanded, the expansion time in the inference can be shortened.

(2)

The data processing system further comprises: a generation unit (for example, library 120, compressor model generation program 302 and high-speed expansion AI model generation program 303, processor 280, circuit) which generates a model of the compressor (for example, compressor model 122) from configuration information (for example, compressor configuration Information 111) of the compressor output from the first interface unit, and generates a model of high-speed expansion AI (for example, high-speed expansion AI model 123) from configuration information of the compressor and a model of prescribed AI (Artificial Intelligence) (for example, input AI model 1110) with the data compressed by the compressor as an input.

According to the configuration described above, since the compressor model and the high-speed expansion AI model are generated by the generation unit, for example, there is no need to manually generate these models, and the high-speed expansion AI can be generated easily.

(3)

The generation unit generates a preprocessing unit (for example, preprocessing unit 1100) for converting the data compressed by the compressor into a data format to be input to the prescribed AI from the configuration information, combines the generated preprocessing unit and the prescribed AI model, and generates a model of the high-speed expansion AI. According to the configuration described above, the high-speed expansion AI can be generated without having to change the configuration of the layer or the like in the prescribed AI model.

(4)

The data processing system further comprises: a learning unit (for example, high-speed expansion AI teaming unit 140, high-speed expansion AI learning program 300, processor 280, circuit) which learns high-speed expansion AI (for example, high-speed expansion AI 142), in which the high-speed expansion AI model has been operably read therein, with data in which learning data (for example, learning data 130) has been compressed by a compressor (for example, compressor 141), in which the compressor model has been operably read therein, as an input.

According to the configuration described above, since the high-speed expansion AI is learned, for example, the learned high-speed expansion AI can be easily used.

(5)

The prescribed AI is AI (for example, AI 1105) that performs analytical processing of data; and the data processing system further comprises: an analyzing unit (for example, high-speed expansion AI analyzing unit 160, high-speed expansion AI analyzing program 301, processor 280, circuit) which performs analytical processing of the data by using the data compressed by the compressor and output by the second interface unit, and the high-speed expansion AI learned by the learning unit.

According to the configuration described above, for example, the analytical processing of data can be sped up.

(6)

The compression/expansion unit is configured by including a coder (for example, coder 114) which encodes the data compressed by the compressor, and a decoder (for example, decoder 115) which decodes the data encoded with the coder; and the compression/expansion unit further comprises: a third interface unit (for example, data writing program 400, processor 220, circuit) which stores, in a storage (for example, storage 112), the data in which the data compressed by the compressor has been encoded using the coder; and a fourth interface unit (for example, expanded data reading program 401, processor 220, circuit) which reads the data from the storage, decodes the read data with the decoder, expands the decoded data with the expander, and outputs the expanded data, and the second interface unit reads the data from the storage, decodes the read data with the decoder, and outputs the decoded data (for example, see FIG. 8).

According to the configuration described above, since the data that was compressed and encoded is stored in the storage, for example, it is possible to reduce the data volume of the storage, and speed up the inference.

(7)

The compressor comprises a padder (for example, padder 1301) which pads the data for causing the input data to be a data size to be received by an encoder part (for example, encoder 1303) of the compressor; and the coder comprises a padder (for example, padder 1306) which pads the data for causing the data compressed by the compressor to be a data size to be received by a hyper encoder part (for example, hyper encoder 1308) of the coder.

According to the configuration described above, since the number of elements of the data compressed by the compressor can be reduced, for example, the compression ratio will improve, and the data volume of the storage can be further reduced.

Moreover, the foregoing configurations may be suitably changed, replaced, combined or omitted to the extent that such change, replacement, combination or omission does not exceed the subject matter of the present invention.

### REFERENCE SIGNS LIST

101 . . . compression/expansion unit, 402 . . . compressed data reading program, 403 . . . compressor configuration information return program.

1. A data processing system comprising a compression/expansion unit configured by including a compressor which compresses data, and an expander which expands the data compressed by the compressor,
wherein the compression/expansion unit comprises:
a first interface unit capable of outputting configuration information of the compressor; and
a second interface unit capable of outputting the data compressed by the compressor.

2. The data processing system according to claim 1, further comprising:
a generation unit which generates a model of the compressor from configuration information of the compressor output from the first interface unit, and generates a model of high-speed expansion AI from configuration information of the compressor and a model of prescribed AI (Artificial Intelligence) with the data compressed by the compressor as an input.

3. The data processing system according to claim 2,
wherein the generation unit generates a preprocessing unit for converting the data compressed by the compressor into a data format to be input to the prescribed AI from the configuration information, combines the generated preprocessing unit and the prescribed AI model, and generates a model of the high-speed expansion AI.

4. The data processing system according to claim 2, further comprising:
a learning unit which learns high-speed expansion AI, in which the high-speed expansion AI model has been operably read therein, with data in which learning data has been compressed by a compressor, in which the compressor model has been operably read therein, as an input.

5. The data processing system according to claim 4, wherein:
the prescribed AI is AI that performs analytical processing of date; and
the data processing system further comprises:
an analyzing unit which performs analytical processing of the data by using the data compressed by the compressor and output by the second interface unit, and the high-speed expansion AI learned by the learning unit.

6. The data processing system according to claim 1, wherein:
the compression/expansion unit is configured by including a coder which encodes the data compressed by the compressor, and a decoder which decodes the data encoded with the coder; and
the compression/expansion unit further comprises:
a third interface unit which stores, in a storage, the data in which the data compressed by the compressor has been encoded using the coder; and
a fourth interface unit which reads the data from the storage, decodes the read data with the decoder, expands the decoded data with the expander, and outputs the expanded data, and
the second interface unit reads the data from the storage, decodes the read data with the decoder, and outputs the decoded data.

7. The data processing system according to claim 6, wherein:
the compressor comprises a padder which pads the data for causing the input data to be a data size to be received by an encoder part of the compressor; and
the coder comprises a padder which pads the data for causing the data compressed by the compressor to be a data size to be received by a hyper encoder part of the coder.

8. A data processing method in a data processing system comprising a compression/expansion unit configured by including a compressor which compresses data, and an expander which expands the data compressed by the compressor, wherein the method includes the steps of the compression/expansion unit:
outputting configuration information of the compressor; and
outputting the data compressed by the compressor.
